(19) United States
(12) Patent Application Publication
(10) Pub. No.: US 2016/0252406 A1
(43) Pub. Date: Sep. 1, 2016

(54) TEMPERATURE SENSOR USING PIEZOELECTRIC RESONATOR AND METHODS OF MEASURING TEMPERATURE

(71) Applicant: CALIFORNIA INSTITUTE OF TECHNOLOGY, Pasadena, CA (US)

(72) Inventors: Stewart Sherrit, La Crescenta, CA (US); Xiaoqi Bao, San Gabriel, CA (US)

(21) Appl. No.: 15/054,073

(22) Filed: Feb. 25, 2016

Related U.S. Application Data
(60) Provisional application No. 62/126,317, filed on Feb. 27, 2015.

(51) Int. Cl. G01K 11/26; H03H 9/21; H01L 41/09; H03H 9/17

(52) U.S. Cl. CPC G01K 11/26; H03H 9/17; H03H 9/21; H01L 41/09

(57) ABSTRACT

A method of measuring temperature includes positioning a piezoelectric resonator in an environment exhibiting the temperature to be measured, applying an input signal to the piezoelectric resonator to resonate the piezoelectric resonator, varying a frequency of the input signal over a range of input frequencies, determining the resonance frequency of the piezoelectric resonator, and determining the temperature of the environment by referencing the resonance frequency of the piezoelectric resonator. The resonance frequency of the piezoelectric resonator changes according to a change in the temperature of the environment and the resonance frequency of the piezoelectric resonator corresponds to the temperature of the environment.

### CROSS-REFERENCE TO RELATED APPLICATION

This application claims priority to and the benefit of U.S. Provisional Application No. 62/126,317, filed Feb. 27, 2015, the entire content of which is incorporated herein by reference.

### STATEMENT REGARDING FEDERALLY SPONSORED RESEARCH OR DEVELOPMENT

The invention described herein was made in the performance of work under a NASA contract, and is subject to the provisions of Public Law 96-517 (35 USC §202) in which the Contractor has elected to retain title.

### FIELD

The present disclosure relates generally to temperature sensors and, more particularly, to temperature sensors using piezoelectric resonators and methods of measuring temperature.

### BACKGROUND

A variety of different types of temperature sensors exist, including thermocouples, resistive temperature sensors, and infrared temperature sensors. The type of temperature sensor may be selected based on its suitability for the environment in which the temperature measurements will be performed and/or the desired performance characteristics of the temperature sensor.

However, there are a variety of limitations associated with conventional temperature sensors. For instance, some conventional temperature sensors have a slow response time to changing temperatures. Some conventional temperature sensors, such as resistive temperature sensors, have poor thermal sensitivity. Additionally, some conventional temperature sensors may be configured to operate over a relatively narrow temperature range. Furthermore, many conventional temperature sensors require a power supply, which renders these temperature sensors undesirable or unsuitable for particular applications, such as remotely measuring the downhole temperature of an oil well.

### SUMMARY

The present disclosure is directed to various embodiments of a method of measuring temperature. In one embodiment, the method includes positioning a piezoelectric resonator in an environment exhibiting the temperature to be measured, applying an input signal to the piezoelectric resonator to resonate the piezoelectric resonator, varying a frequency of the input signal over a range of input frequencies, and determining a resonance frequency of the piezoelectric resonator. The resonance frequency of the piezoelectric resonator changes according to a change in the temperature of the environment and the resonance frequency of the piezoelectric resonator corresponds to the temperature of the environment. The method also includes determining the temperature of the environment by referencing the resonance frequency of the piezoelectric resonator. Determining the resonance frequency of the piezoelectric resonator may include determining a minimum electrical impedance of the piezoelectric resonator and determining the frequency of the input signal corresponding to the minimum electrical impedance of the piezoelectric resonator. Determining the temperature of the environment may include referencing a lookup table including a resonance frequency spectrum of the piezoelectric resonator mapped to a temperature spectrum. The resonance frequency of the piezoelectric resonator may be from approximately 1 kHz to approximately 100 kHz (e.g., from approximately 2.6 kHz to approximately 80 kHz). The piezoelectric resonator may have a quality factor (Q) from approximately 100 to approximately 1000 (e.g., from approximately 130 to approximately 900). The piezoelectric resonator may be any suitable type of piezoelectric resonator, such as a piezoelectric tuning fork, a flextensional piezoelectric actuator, or an ultrasonic stepped horn resonator. A baseline electrical impedance of the piezoelectric resonator may be at least approximately 50 Ohms. A difference between the baseline electrical impedance and a minimum electrical impedance of the piezoelectric resonator may be at least approximately 20 Ohms. The piezoelectric resonator may be configured to measure temperatures ranging from approximately 0° C. to approximately 250° C.

The present disclosure is also directed to various embodiments of a system for measuring temperature. In one embodiment, the system includes at least one piezoelectric resonator positioned in a subsurface borehole, a signal generator configured to generate an input signal and to vary a frequency of the input signal over a range of input frequencies, a receiver, and an electromagnetic waveguide at least partially positioned in the subsurface borehole. The electromagnetic waveguide is configured to transmit the input signal from the signal generator to the at least one piezoelectric resonator to resonate the piezoelectric resonator. The electromagnetic waveguide is also configured to transmit an electrical impedance of the at least one piezoelectric resonator to the receiver. A minimum electrical impedance of the piezoelectric resonator corresponds to a resonance frequency of the piezoelectric resonator. The resonance frequency of the piezoelectric resonator changes according to a change in the temperature in the subsurface borehole, and the resonance frequency of the piezoelectric resonator corresponds to the temperature in the subsurface borehole. The receiver may include memory storing data correlating a resonance frequency spectrum and/or a minimum electrical impedance spectrum of the piezoelectric resonator to a temperature spectrum. The resonance frequency of the piezoelectric resonator at room temperature may be from approximately 1 kHz to approximately 100 kHz (e.g., from approximately 2.6 kHz to approximately 80 kHz). The piezoelectric resonator may have a quality factor (Q) from approximately 100 to approximately 1000 (e.g., from approximately 130 to approximately 900). A baseline electrical impedance of the piezoelectric resonator may be at least approximately 50 Ohms and a difference between the baseline electrical impedance and the minimum electrical impedance of the piezoelectric resonator may be at least approximately 20 Ohms. The piezoelectric resonator may be any suitable type of piezoelectric resonator, such as a piezoelectric tuning fork, a flextensional piezoelectric actuator, or an ultrasonic stepped horn resonator.

This summary is provided to introduce a selection of features and concepts of embodiments of the present disclosure that are further described below in the detailed description. This summary is not intended to identify key or essential features of the claimed subject matter, nor is it intended to be used in limiting the scope of the claimed subject matter. One or more of the described features may be combined with one or more other described features to provide a workable device.

### BRIEF DESCRIPTION OF THE DRAWINGS

These and other features and advantages of embodiments of the present disclosure will become more apparent by reference to the following detailed description when considered in conjunction with the following drawings. In the drawings, like reference numerals are used throughout the figures to reference like features and components. The figures are not necessarily drawn to scale, nor is every feature in the drawings necessarily required to fall within the scope of the described invention.

FIG. 1 is a flowchart illustrating tasks of a method of measuring temperature according to one embodiment of the present disclosure;

FIG. 2A is a graph of electrical impedance versus frequency of a piezoelectric resonator temperature sensor according to one embodiment of the present disclosure;

FIG. 2B is a graph of resistance versus frequency of the embodiment of the piezoelectric resonator temperature sensor in FIG. 2A in parallel with a 50 Ohm resistor;

FIG. 3 is a graph of electrical impedance versus frequency of a piezoelectric resonator temperature sensor according to another embodiment of the present disclosure;

FIG. 4 is a graph of electrical impedance versus frequency of a piezoelectric resonator temperature sensor according to a further embodiment of the present disclosure;

FIG. 5 is a graph of the temperature dependence of the material properties that control the resonance frequency of the piezoelectric resonator according to one embodiment of the present disclosure; and

FIG. 6 is a schematic view of a system for measuring temperature in a subsurface borehole.

### DETAILED DESCRIPTION

The present disclosure is directed to various methods of measuring temperature using piezoelectric resonators. When the piezoelectric resonators of the present disclosure are subject to temperature changes, changes in material properties of the piezoelectric resonator and/or mechanical properties of the piezoelectric resonator change the resonance frequency of the piezoelectric resonator. The piezoelectric resonators may be calibrated and a resonance frequency spectrum of the piezoelectric resonators may be mapped to a temperature spectrum. Accordingly, the resonance frequency of the piezoelectric resonators may be used to determine the corresponding temperature of the environment in which the piezoelectric resonators are located. Additionally, a minimum electrical impedance spectrum of the piezoelectric resonators may be mapped to a temperature spectrum and the minimum electrical impedance of the piezoelectric resonator may be used to determine the corresponding temperature of the environment in which the piezoelectric resonators are located.

The piezoelectric resonators and the temperature measurement methods of the present disclosure may be suitable for use in a variety of temperature measurement applications, such as, for instance, in the oil industry (e.g., measuring the downhole temperature of an oil well) and/or in aeronautical and space operations (e.g., measuring planetary atmospheric temperature, oceanic temperature, and/or deep drill exploration hole temperature). For instance, the temperature sensors of the present disclosure may be used as a passive downhole temperature sensor that is readable remotely from the surface using an electromagnetic waveguide system (e.g., concentric pipes downhole functioning as an electromagnetic waveguide). Accordingly, the temperature sensors of the present disclosure may be passive devices with no internal electric power supply and remotely readable through an electromagnetic waveguide.

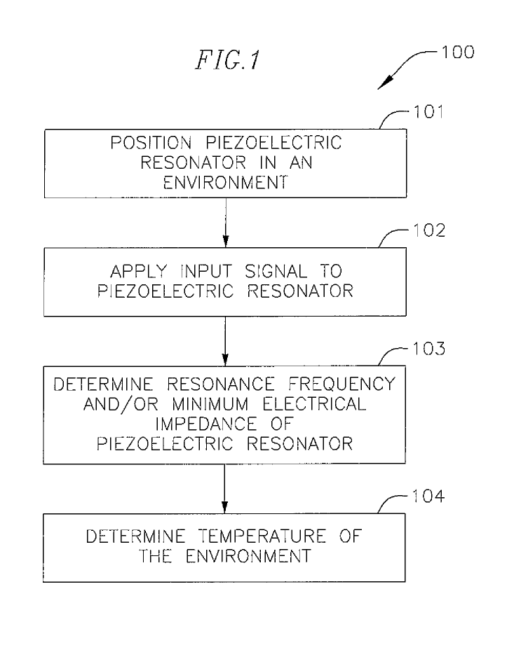

With reference now to FIG. 1, a method 100 of measuring temperature according to one embodiment of the present disclosure includes a task 101 of positioning a piezoelectric resonator in an environment exhibiting a temperature to be measured. The piezoelectric resonator may be any suitable type of resonator, such as, for instance, a piezoelectric tuning fork, a flextensional piezoelectric actuator, or an ultrasonic stepped horn piezoelectric resonator. In one or more embodiments, the piezoelectric resonator includes a sealed enclosure and at least one piezoelectric layer on a substrate (e.g., a diaphragm or tines of a tuning fork) housed in the sealed enclosure.

The resonance frequency of the piezoelectric resonator changes (i.e., shifts) according to changes in the temperature of the environment in which the resonator is located (i.e., the resonance frequency of the piezoelectric resonator varies according to the temperature of the piezoelectric resonator). In one or more embodiments, the resonance frequency of the piezoelectric resonator decreases with increasing temperature (i.e., the resonance frequency of the resonator is inversely related to the temperature of the piezoelectric resonator). A variety of factors may contribute to the change in resonance frequency of the piezoelectric resonator as a function of temperature, including changes in material properties of the piezoelectric resonator (e.g., changes in the elastic constant and/or the coupling constant of the piezoelectric resonator) and/or thermal strains affecting the boundary conditions of the piezoelectric resonator. In one or more embodiments, the resonance frequency of the piezoelectric resonator may be primarily dependent on the elastic properties of the constituent materials of the piezoelectric resonator and the dimensions of the piezoelectric resonator. Additionally, in one or more embodiments, a baseline dielectric constant of the resonator is the most temperature dependent property of the piezoelectric resonator. In one or more embodiments, the dependence of the baseline dielectric constant on the temperature increases as the temperature nears the Curie temperature of the piezoelectric resonator. Additionally, in one or more embodiments, the dependence of the dielectric constant on the temperature varies linearly over small temperature ranges when the temperature is distant from the Curie temperature of the piezoelectric resonator. Additionally, in one or more embodiments, the electrical impedance of the piezoelectric resonator drops due to the increase of the dielectric constant of the resonator with increasing temperature (i.e., the baseline electrical impedance and the electrical impedance at resonance decrease due to the increase of the dielectric constant of the resonator with increasing temperature).

With continued reference to FIG. 1, the method 100 also includes a task 102 of applying an input signal (e.g., an alternating current (AC) electric field) to the one or more piezoelectric layers of the piezoelectric resonator. The application of the AC electric field to the one or more piezoelectric layers causes the piezoelectric resonator to resonate (e.g., vibrate) due to the inverse piezoelectric effect. The method also includes a task 103 of determining the resonance frequency and/or minimum electrical impedance of the piezoelectric resonator. The resonance frequency of the piezoelectric resonator corresponds to the minimum electrical impedance of the piezoelectric resonator. Accordingly, the resonance frequency of the piezoelectric resonator may be determined by varying the frequency of the input signal (e.g., the AC electric field) applied to the resonator and determining the frequency corresponding to the minimum electrical impedance of the piezoelectric resonator (i.e., the minimum impedance frequency is the resonance frequency).

The method also includes a task 104 of determining the temperature of the environment in which the piezoelectric resonator is located by referencing the resonance frequency of the piezoelectric resonator. The piezoelectric resonator may be calibrated and a resonance frequency spectrum of the piezoelectric resonator may be mapped to a temperature spectrum (e.g., in a lookup table). That is, the piezoelectric resonator may be calibrated to correlate the resonance frequency of the piezoelectric resonator with the temperature of the environment in which the piezoelectric resonator is located. Accordingly, the resonance frequency of the piezoelectric resonator may be used to determine the corresponding temperature of the environment in which piezoelectric resonator is located (e.g., referencing the lookup table and determining the temperature that corresponds to the resonance frequency of the piezoelectric resonator).

In one or more embodiments, the task 104 may include determining the temperature of the environment in which the piezoelectric resonator is located by referencing the minimum electrical impedance of the piezoelectric resonator. The minimum electrical impedance of the piezoelectric resonator is the electrical impedance of the piezoelectric resonator at resonance frequency. The piezoelectric resonator may be calibrated and a minimum electrical impedance spectrum of the piezoelectric resonator may be mapped (i.e., correlated) to a temperature spectrum (e.g., in a lookup table). Accordingly, the minimum electrical impedance of the resonator may be used to determine the corresponding temperature of the environment in which piezoelectric resonator is located (e.g., referencing the lookup table and determining the temperature that corresponds to the minimum electrical impedance of the piezoelectric resonator).

In one or more embodiments, the resonator may have a relatively low resonance frequency at room temperature, such as, for instance, from approximately 1 kHz to approximately 100 kHz. In one or more embodiments, the resonator may have a resonance frequency from approximately 2.6 kHz to approximately 80 kHz at room temperature. In one or more embodiments, the lower the resonance frequency of the piezoelectric resonator, the lower the piezoelectric resonator can be deployed (e.g., down an oil well or a deep drill exploration hole) due to signal attenuation. In general, higher frequency signals attenuate faster than relatively lower frequency signals and this enables lower frequency piezoelectric resonators to be deployed deeper below the surface than relatively higher frequency piezoelectric resonators. For instance, a lower frequency piezoelectric resonator may deployed deeper below the surface than a relatively higher frequency piezoelectric resonator when the piezoelectric resonator is used as a passive downhole temperature sensor that is readable remotely from the surface using an electromagnetic waveguide system (e.g., concentric pipes downhole functioning as an electromagnetic waveguide).

Additionally, in one or more embodiments, the piezoelectric resonator may have a relatively high quality factor (Q), such as, for instance, from approximately 100 to approximately 1000. In one or more embodiments, the piezoelectric resonator may have a quality factor (Q) from approximately 130 to approximately 900. The relatively high quality factor (Q) is configured to produce a relatively large electrical impedance drop at resonance frequency. Additionally, in one or more embodiments, the piezoelectric resonator may have a baseline (i.e., off resonance) electrical impedance of approximately 50 Ohms or more. In one or more embodiments, the piezoelectric resonator may be configured to measure temperatures ranging from approximately 0° C. to approximately 250° C.

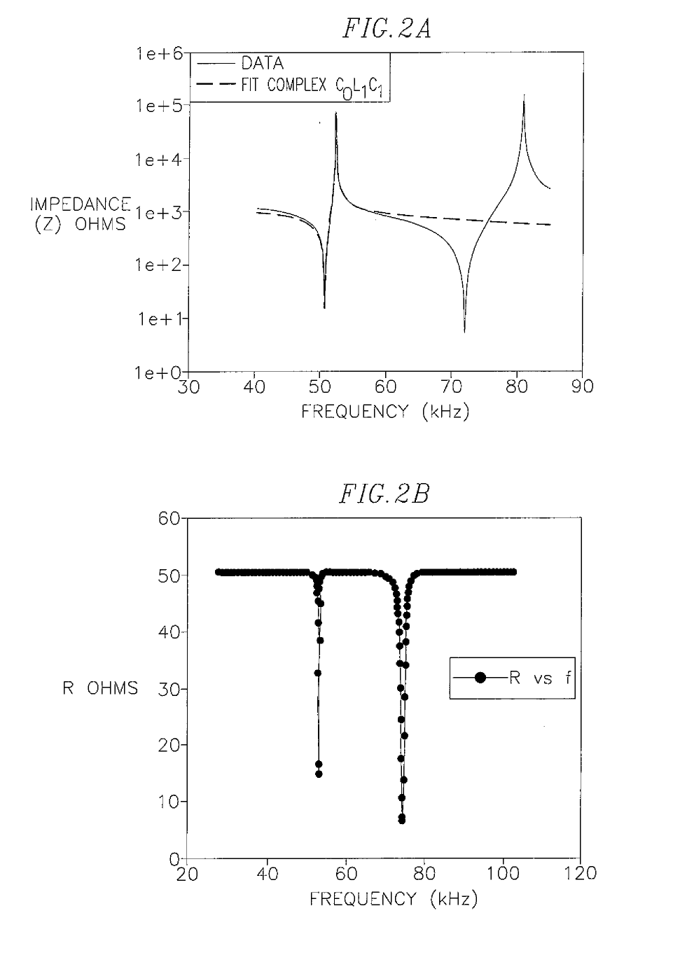

FIG. 2A is a graph of electrical impedance versus frequency for a piezoelectric resonator at room temperature according to one embodiment of the present disclosure. In the illustrated embodiment, the resonator has two resonance frequencies at room temperature of approximately 50.5 kHz and approximately 72 kHz and quality factors (Q) at room temperature of approximately 900 and approximately 750.

FIG. 2B is a graph of resistance versus frequency of the embodiment of the piezoelectric resonator in FIG. 2A in parallel with a 50 Ohm resistor. As illustrated in FIG. 2B, the baseline (i.e., off-resonance) resistance is approximately 50 Ohms. Additionally, as illustrated in FIG. 2B, the resistance drops to approximately 15 Ohms for the first resonance peak (50 kHz) and drops to approximately 6 Ohms for the second resonance peak (72 kHz). In one or more embodiments, the difference between the minimum electrical impedance (i.e., the impedance at resonance frequency) and the base electrical impedance may be at least approximately 20 Ohms, such as, for instance, 25 Ohms or more.

FIG. 3 is a graph of electrical impedance versus frequency for a piezoelectric resonator temperature sensor at room temperature according to another embodiment of the present disclosure. In the illustrated embodiment, the resonator has a resonance frequency at room temperature of approximately 2.6 kHz and quality factor (Q) at room temperature of approximately 130. Additionally, in the illustrated embodiment, the resonator has a minimum electrical impedance at room temperature of approximately 20 Ohms.

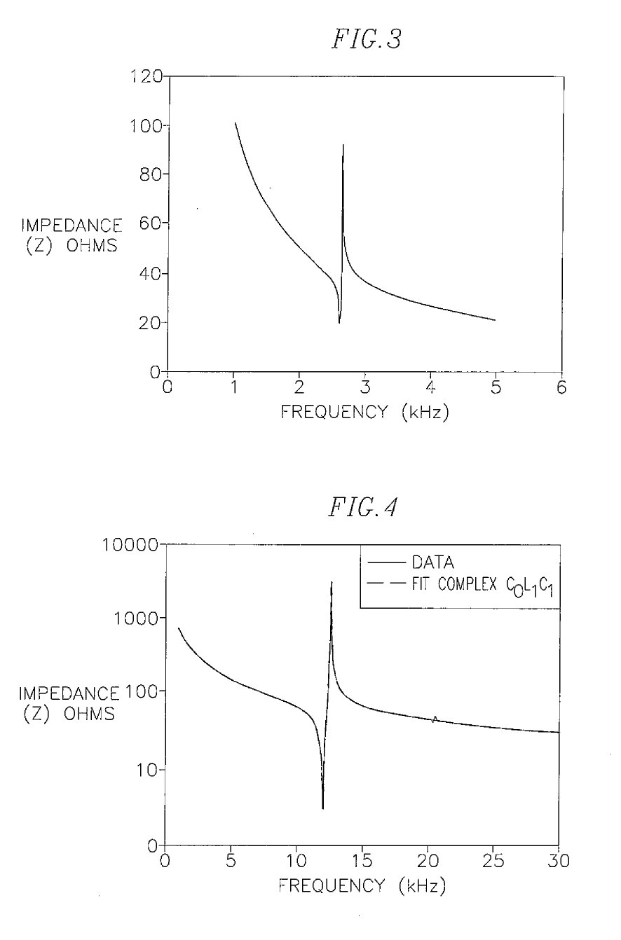

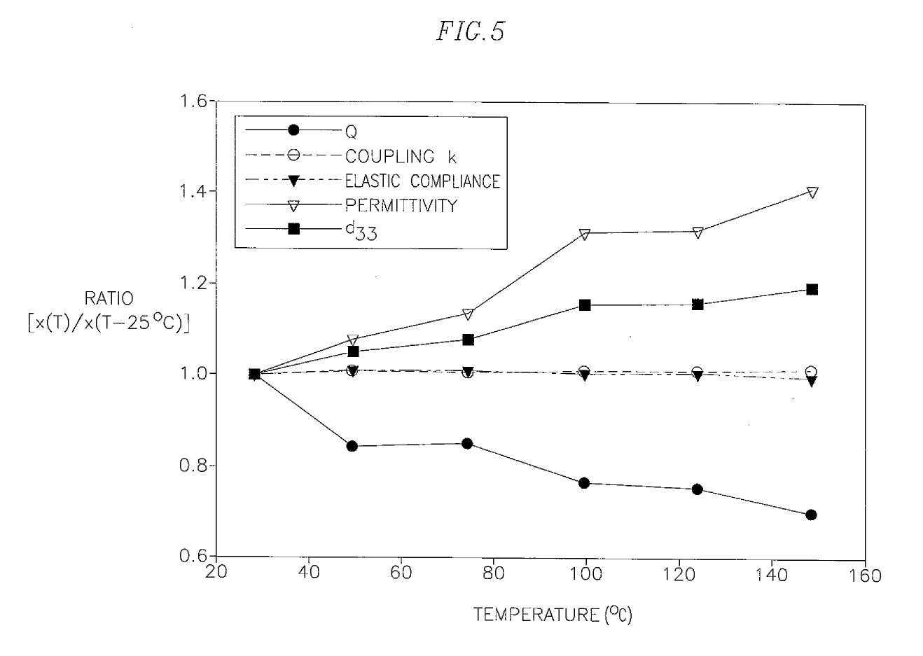

FIG. 4 is a graph of electrical impedance versus frequency for a piezoelectric resonator temperature sensor at room temperature according to another embodiment of the present disclosure. In the illustrated embodiment, the resonator has a resonance frequency at room temperature of approximately 12 kHz and quality factor (Q) at room temperature of approximately 230. Additionally, in the illustrated embodiment, the resonator has a minimum electrical impedance at room temperature of approximately 4 Ohms.

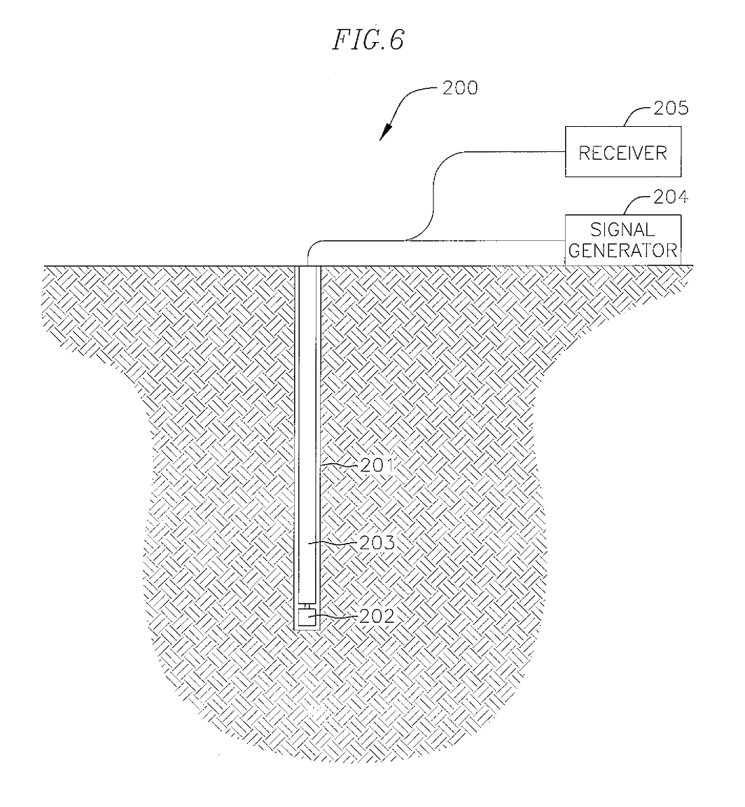

FIG. 5 depicts the ratio of the change (x(T)/x(T−25° C.)) of the quality factor (Q), the coupling constant (k), the elastic compliance, the permittivity, and the piezoelectric coefficient (d₃₃) of a piezoelectric resonator as a function of temperature (T ° C.) according to one embodiment of the present disclosure. In FIG. 5, the ratio of change for each material property is calculated as a ratio between the value of the material property for a given temperature (i.e., x(T)) and the value of the material property at a temperature 25° C. less than the given temperature (i.e., x(T−25° C.)). These material properties (i.e., quality factor (Q), coupling constant (k), elastic compliance, permittivity, and piezoelectric coefficient (d₃₃)) control the resonance frequency of the piezoelectric resonator. Accordingly, FIG. 5 illustrates the temperature dependence of the material properties that control the resonance frequency of the piezoelectric resonator according to one embodiment of the present disclosure. As illustrated in FIG. 5, the elastic compliance and the coupling constant (k) of the piezoelectric resonator remain constant or substantially constant with increasing temperature (i.e., the elastic compliance and the coupling constant (k) of the piezoelectric resonator are not temperature dependent). Additionally, as illustrated in FIG. 5, the ratio of change of the permittivity and the piezoelectric coefficient (d₃₃) of the piezoelectric resonator increase with increasing temperature and the ratio of change of the quality factor (Q) of the resonator decreases with increasing temperature. In one or more embodiments, the piezoelectric coefficient (d₃₃) increases with the square root of the temperature. Together, these changes in the material properties of the piezoelectric resonator result in the resonance frequency of the piezoelectric resonator decreasing with increasing temperature. As described above, the change (i.e., shift) in the resonance frequency of the piezoelectric resonator may be mapped as a function of the change in temperature such that the resonance frequency of the piezoelectric resonator may be referenced to determine the corresponding temperature of the environment in which the piezoelectric resonator is located.

FIG. 6 is a schematic view of a system 200 for measuring the temperature in a subsurface borehole 201. The subsurface borehole 201 may be any suitable type of bore, such as, for instance, a wellbore in an oil field. In one or more embodiments, the wellbore may be lined with a borehole casing to provide structural support to the borehole. In the illustrated embodiment, the system 200 includes a piezoelectric resonator 202 positioned in the subsurface borehole 201 (e.g., at a bottom portion of the subsurface borehole 201), an electromagnetic waveguide 203 at least partially positioned in the subsurface borehole 201 and above the piezoelectric resonator 202, a signal generator 204 coupled to the electromagnetic waveguide 203, and a receiver 205 coupled to the electromagnetic waveguide 203. The piezoelectric resonator 202 may have any suitable combination or sub-combination of properties or characteristics described above with reference to FIGS. 1-5. For instance, in one or more embodiments, the piezoelectric resonator 202 may have a quality factor (Q) at room temperature from approximately 100 to approximately 1000, a resonance frequency at room temperature from approximately 1 kHz to approximately 100 kHz, and a baseline (i.e., off resonance) electrical impedance of approximately 50 Ohms or more at room temperature. Additionally, the piezoelectric resonator 202 may be any suitable type of piezoelectric resonator, such as, for instance, a piezoelectric tuning fork, a flextensional piezoelectric actuator, or an ultrasonic stepped horn resonator.

The signal generator 204 is configured to generate an alternating current (AC) signal. The signal generator 204 is also configured to vary the frequency of the AC signal over a range of frequencies. The AC signal may be either a pulsed signal or a continuous wave signal. The electromagnetic waveguide 203 is configured to transmit the AC signal from the signal generator 204 to the piezoelectric resonator 202. Suitable electromagnetic waveguides are described in International Patent Application Publication No. WO 2009/032899, filed Sep. 4, 2008, the entire content of which is incorporated herein by reference. When the AC signal is transmitted to the piezoelectric resonator 202 by the electromagnetic waveguide 203, the piezoelectric resonator 202 resonates due to the inverse piezoelectric effect.

The receiver 205 is configured to receive a signal from the electromagnetic waveguide 203 including an electrical impedance of the piezoelectric resonator 202 (i.e., the electromagnetic waveguide 203 is configured to transmit an electrical impedance of the piezoelectric resonator 202 to the receiver 205). In one or more embodiments, the receiver 205 may be a computer including a bus for receiving signals from the electromagnetic waveguide 203 for storage, processing, and/or display. In one or more embodiments, the receiver 205 may include a display with a graphical user interface. Accordingly, as the signal generator 204 varies the frequency of the AC signal that is transmitted to the piezoelectric resonator 202 by the electromagnetic waveguide 203, the electrical impedance of the piezoelectric resonator 202, which is transmitted to the receiver 205 by the electromagnetic waveguide 203, varies. The receiver 205 may store, process, and/or display a graph of the electrical impedance of the piezoelectric resonator 202 as a function of the frequency of the AC signal, as shown, for instance, in FIGS. 2A, 3, and 4. Additionally, the receiver 205 may be configured to determine the minimum electrical impedance of the piezoelectric resonator 202 by referencing the graph of the electrical impedance of the piezoelectric resonator 202 as a function of the frequency of the AC signal. Additionally, in one or more embodiments, the receiver 205 may be configured to determine the resonance frequency of the piezoelectric resonator 202 by determining the frequency of the AC signal corresponding to the minimum electrical impedance of the piezoelectric resonator 202 (i.e., the minimum impedance frequency is the resonance frequency).

In general, due to signal attenuation in the electromagnetic waveguide 203 (e.g., signal attenuation from the signal generator 204 to the piezoelectric resonator 202 and/or signal attenuation from the piezoelectric resonator 202 to the receiver 205), the lower the resonance frequency of the piezoelectric resonator 202, the lower the piezoelectric resonator 202 can be deployed down the subsurface borehole 201.

Additionally, one or more embodiments, the receiver 205 may include memory (e.g., a hard disk drive (HDD), a memory card, magnetic tape, and/or a compact disk) storing data correlating a resonance frequency spectrum and/or a minimum electrical impedance spectrum of the piezoelectric resonator 202 to a temperature spectrum (e.g., the receiver may store the data in a lookup table). As described above, the minimal electrical impedance of the piezoelectric resonator 202 and the resonance frequency of the piezoelectric resonator 202 vary according to the temperature of the environment in which the piezoelectric resonator 202 is located. In one or more embodiments, the piezoelectric resonator 202 may be calibrated and the resonance frequency spectrum and/or the minimum electrical impedance spectrum of the piezoelectric resonator 202 may be mapped to a temperature spectrum (e.g., in a lookup table) and this calibration data may be stored in the memory of the receiver 205. Accordingly, in one or more embodiments, the receiver 205 may be configured to determine the temperature of the portion of the subsurface borehole 201 in which piezoelectric resonator is located by referencing the resonance frequency and/or the minimum electrical impedance of the piezoelectric resonator 202 (e.g., referencing the lookup table stored in the memory and determining the temperature that corresponds to the resonance frequency and/or the minimum electrical impedance of the piezoelectric resonator 202).

While this invention has been described in detail with particular references to embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention. Although relative terms such as “outer,” “inner,” “upper,” “lower,” and similar terms have been used herein to describe a spatial relationship of one element to another, it is understood that these terms are intended to encompass different orientations of the various elements and components of the invention in addition to the orientation depicted in the figures. Additionally, as used herein, the term “substantially,” “generally,” and similar terms are used as terms of approximation and not as terms of degree, and are intended to account for the inherent deviations in measured or calculated values that would be recognized by those of ordinary skill in the art. Furthermore, as used herein, when a component is referred to as being “on” or “coupled to” another component, it can be directly on or attached to the other component or intervening components may be present therebetween. Further, any described feature is optional and may be used in combination with one or more other features to achieve one or more benefits.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Additionally, the system and/or any other relevant devices or components according to embodiments of the present invention described herein may be implemented utilizing any suitable hardware, firmware (e.g. an application-specific integrated circuit), software, or a combination of software, firmware, and hardware.

What is claimed is:

1. A method of measuring temperature, comprising:
positioning a piezoelectric resonator in an environment exhibiting the temperature to be measured,
applying an input signal to the piezoelectric resonator to resonate the piezoelectric resonator;
varying a frequency of the input signal over a range of input frequencies;
determining a resonance frequency of the piezoelectric resonator, wherein the resonance frequency of the piezoelectric resonator changes according to a change in the temperature of the environment, and wherein the resonance frequency of the piezoelectric resonator corresponds to the temperature of the environment; and
determining the temperature of the environment by referencing the resonance frequency of the piezoelectric resonator.

2. The method of claim 1, wherein the determining the resonance frequency of the piezoelectric resonator comprises determining a minimum electrical impedance of the piezoelectric resonator and determining the frequency of the input signal corresponding to the minimum electrical impedance of the piezoelectric resonator.

3. The method of claim 1, wherein the determining the temperature of the environment comprises referencing a lookup table comprising a resonance frequency spectrum of the piezoelectric resonator mapped to a temperature spectrum.

4. The method of claim 1, wherein the resonance frequency of the piezoelectric resonator at room temperature is from approximately 1 kHz to approximately 100 kHz.

5. The method of claim 1, wherein the resonance frequency of the piezoelectric resonator at room temperature is from approximately 2.6 kHz to approximately 80 kHz.

6. The method of claim 1, wherein a baseline electrical impedance of the piezoelectric resonator is at least approximately 50 Ohms.

7. The method of claim 6, wherein a difference between the baseline electrical impedance and a minimum electrical impedance of the piezoelectric resonator is at least approximately 20 Ohms.

8. The method of claim 1, wherein the piezoelectric resonator has a quality factor (Q) from approximately 100 to approximately 1000.

9. The method of claim 1, wherein the piezoelectric resonator has a quality factor (Q) from approximately 130 to approximately 900.

10. The method of claim 1, wherein the piezoelectric resonator is a piezoelectric tuning fork.

11. The method of claim 1, wherein the piezoelectric resonator is a flextensional piezoelectric actuator.

12. The method of claim 1, wherein the piezoelectric resonator is an ultrasonic stepped horn resonator.

13. The method of claim 1, wherein the piezoelectric resonator is configured to measure temperatures ranging from approximately 0° C. to approximately 250° C.

14. A system for measuring temperature, comprising:
at least one piezoelectric resonator positioned in a subsurface borehole;
a signal generator configured to generate an input signal and to vary a frequency of the input signal over a range of input frequencies;
a receiver; and
an electromagnetic waveguide at least partially positioned in the subsurface borehole, the electromagnetic waveguide configured to transmit the input signal from the signal generator to the at least one piezoelectric resonator to resonate the piezoelectric resonator and configured to transmit an electrical impedance of the at least one piezoelectric resonator to the receiver,
wherein a minimum electrical impedance of the piezoelectric resonator corresponds to a resonance frequency of the piezoelectric resonator,
wherein the resonance frequency of the piezoelectric resonator changes according to a change in the temperature in the subsurface borehole, and
wherein the resonance frequency of the piezoelectric resonator corresponds to the temperature in the subsurface borehole.

15. The system of claim 14, wherein the receiver further comprises memory storing data correlating a resonance frequency spectrum and/or a minimum electrical impedance spectrum of the piezoelectric resonator to a temperature spectrum.

16. The system of claim 14, wherein the resonance frequency of the piezoelectric resonator at room temperature is from approximately 2.6 kHz to approximately 80 kHz.

17. The system of claim 14, wherein a baseline electrical impedance of the piezoelectric resonator is at least approximately 50 Ohms.

18. The system of claim 17, wherein a difference between the baseline electrical impedance and the minimum electrical impedance of the piezoelectric resonator is at least approximately 20 Ohms.

19. The system of claim 14, wherein the piezoelectric resonator has a quality factor (Q) from approximately 130 to approximately 900.

20. The system of claim 14, wherein the piezoelectric resonator is selected from the group of resonators consisting of a piezoelectric tuning fork, a flextensional piezoelectric actuator, and an ultrasonic stepped horn resonator.
